(19) United States
(12) Patent Application Publication
(10) Pub. No.: US 2007/0231485 A1
(43) Pub. Date: Oct. 4, 2007

(54) Silane process chamber with double door seal

(76) Inventors: William A. Moffat, San Jose, CA (US); Craig McCoy, San Jose, CA (US); Stuart Allen, Gilroy, CA (US)

Correspondence Address: MICHAEL A. GUTH, 2-2905 EAST CLIFF DRIVE, SANTA CRUZ, CA, 95062, US

(21) Appl. No.: 11/585,656

(22) Filed: Oct. 23, 2006

Related U.S. Application Data
(63) Continuation-in-part of application No. 10/656,840, filed on Sep. 5, 2003.

(51) Int. Cl. C23C 16/00

(52) U.S. Cl. 427/248.1; 118/733

(57) ABSTRACT

A process chamber for the coating of substrates with silanes with a double door seal. The double door seal may have a cavity between the seals which may be evacuated or pressurized, including with an inert gas. An apparatus for the coating of substrates comprising a process oven, a gas plasma subsystem, a metered chemical withdrawal subsystem, a vacuum subsystem, a vaporization subsystem, and a double door seal. A process oven utilizing a double sealed door with pressurized inert gas between the seals to reduce oxygen contamination and risks associated with silane processes.

### CROSS-REFERENCE TO RELATED APPLICATIONS

This application is a continuation in part of U.S. patent application Ser. No. 10/656,840 to Moffat et al., filed Sep. 5, 2003, which is hereby incorporated by reference. This application relates to U.S. patent application Ser. No. 10/843,774 to Moffat et al., filed May 11, 2004, which is hereby incorporated by reference. This application relates to U.S. patent application Ser. No. 10/695,633 to Moffat et al., filed Oct. 27, 2003, which is hereby incorporated by reference

### BACKGROUND

1. Field of the Invention

This invention relates to process chambers, and in particular to a process chamber and process for the safer and lower contamination coating of substrates involving vapors and vaporous silanes using a chamber with a double door seal.

2. Description of the Related Art

The application of coatings onto substrates and other workpieces is required as a process step in many industrial fields. An example of such a process is the coating of a silicon wafer with a layer of Hexamethyldisalizane (HMDS). This coating process is used to promote the adhesion of organic layers such as photoresist to the inorganic silicon wafer. The HMDS molecule has the ability to adhere to the silicon wafer and also to be adhered to by an organic additional layer. For example, silicon wafers would be baked for 30 minutes in a 150 C. oven for 30 minutes to dehydrate them. The silicon wafers would then be sprayed with HMDS. The excess HMDS would then be spun off of the silicon wafer. A typical process of this type would result in a HMDS monolayer on the surface of the silicon wafer.

Some coating processes based on the above mentioned type of process require a higher pressure. The HMDS is preheated to create a higher vapor pressure. Typical figures are preheating of the HMDS to 10° C. to produce up to 400 Torr pressure of HMDS vapor while limiting the pressure in the process oven at 300 Torr to avoid condensation of the HMDS.

With the evolution of coating processes, more chemicals are being used. Many of the chemicals now used are silanes which are significantly more sensitive to oxygen with regard to the success of the process, and which also have a significant risk associated with the meeting of the silane vapor with oxygen.

Processes involving the preheating of deposition chemicals, especially silanes, have the risk that if the deposition chemicals are raised to a temperature above their auto-ignition temperature, exposure to oxygen can result in fire or explosion. With some chemical vapors, the auto-ignition temperature may be below ambient temperature, and the risk of fire or explosion in the presence of oxygen may exist even without preheating. In addition to the risk of explosion, ignition of silanes within the process chamber may leave residues, and block inlet lines, in a way that renders the chamber useless.

In addition to the safety risks mentioned above, the introduction of oxygen into silane coating processes may alter the process in an unwanted way.

Thus, the unintentional introduction of oxygen to a process chamber using self-igniting chemicals such as silanes is rigorously guarded against. For example, purge chemicals which may be used in process chambers, such as nitrogen, are provided with a very low amount of oxygen. Also, these gasses may be passed through a purifier which further reduces the oxygen content. Some purifiers claim to reduce the oxygen content to less than 0.1 parts per billion.

A source of oxygen contamination risk in a process chamber is the door seal which seals the process chamber door. The door typically is opened on a regular basis and is subjected to wear and particles which may interfere with its proper sealing.

What is called for is a process chamber for the processing of silanes and other dangerous oxygen sensitive vapors which has a door seal which greatly minimizes the risk of oxygen contamination in the process chamber.

### SUMMARY

A process chamber for the coating of substrates with silanes with a double door seal. The double door seal may have a cavity between the seals which may be evacuated or pressurized, including with an inert gas. An apparatus for the coating of substrates comprising a process oven, a gas plasma subsystem, a metered chemical withdrawal subsystem, a vacuum subsystem, a vaporization subsystem, and a double door seal. A process oven utilizing a double sealed door with pressurized inert gas between the seals to reduce oxygen contamination and risks associated with silane processes.

### BRIEF DESCRIPTION OF THE DRAWINGS

FIG. 1 is a pictorial representation of portions of one embodiment of the invention highlighting the chemical withdrawal, infuse, and vaporization subsystems.

FIG. 2 is a pictorial representation of portions of one embodiment of the invention highlighting the chemical withdrawal and infuse subsystems.

FIG. 3 is a representational piping schematic of one embodiment of the present invention.

FIG. 4 is a pictorial representation of portions of one embodiment of the present invention highlighting the vacuum and gas delivery subsystems.

FIG. 5 is a front isometric view of one embodiment of the present invention.

FIG. 6 is a rear isometric view of one embodiment of the present invention.

FIG. 7 is a partial cutaway side view of one embodiment of the present invention.

FIG. 8 is a blown up section of the partial side view of FIG. 7.

FIG. 9 is a side view of one embodiment of the present invention.

FIG. 10 is a rear view of one embodiment of the present invention.

FIG. 11 is a top view of one embodiment of the present invention.

FIG. 12 is a rear view of one embodiment of the present invention.

FIG. 13 is a partial cutaway view of one embodiment of the present invention.

FIG. 14 is a view of the process oven interior according to one embodiment of the present invention.

FIG. 15 is a view of the process oven interior according to one embodiment of the present invention.

FIG. 16 is a view of the process oven interior according to one embodiment of the present invention.

FIG. 17 is a view of a process oven with a double door seal according to some embodiments of the present invention.

### DETAILED DESCRIPTION

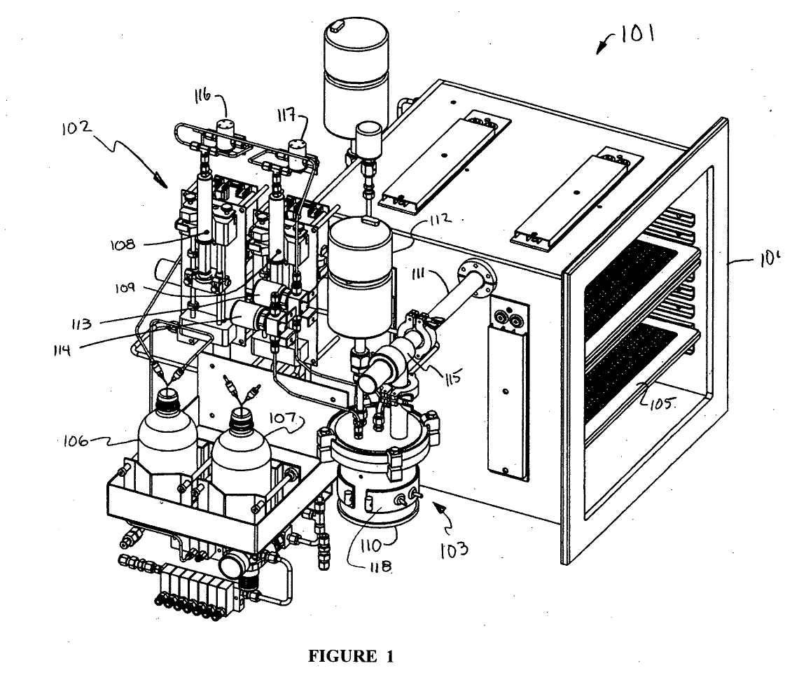

In one embodiment of the present invention, as seen in FIG. 1, chemical vapor deposition apparatus 101 has a fluid input portion 102, a vaporization portion 103, and a process oven 104. Process oven 104 may be controlled with regard to both temperature and pressure. Fluid reservoirs 106, 107 provide the chemicals for the fluid input portion 102. Fluid reservoirs 106, 107, may be manufacturer's source bottles in some embodiments. Fluid reservoirs may contain the same fluid, allowing for the easy replacement of one reservoir if empty without disruption of the deposition process, or may contain separate chemicals. In some applications, water may be used as one of the chemicals in order to facilitate some rehydration of the substrate.

Chemicals in the fluid reservoirs 106, 107, are withdrawn into fluid input portion 102 by syringe pumps 108, 109. Although syringe pumps are used in this embodiment, other methods of withdrawal may be used, including peristaltic pumps and other appropriate methods. Chemical withdraw valves 116, 117, provide isolation between fluid reservoirs 106, 107, and syringe pumps 108, 109. Chemical withdraw valves 116, 117, are opened prior to withdrawal of chemicals from fluid reservoirs 106, 107.

Chemical infusion valves 113, 114 provide isolation between syringe pumps 108, 109, and the vapor chamber 110. The vapor chamber 110 is surrounded by vapor chamber heater 118. Although the vapor chamber heater is external to the vapor chamber in this embodiment, the vapor chamber heater may be internal to the vapor chamber or integral to the vapor chamber. The vapor chamber heater 110 may be P/N MBH00233 manufactured by Tempco, of Wood Dale, Ill., or other suitable heater. The vapor chamber 110 is fluidically coupled to process oven 104 by heated vapor line 111. The vapor chamber 110 may be isolated from process oven 104 by the operation of heated vapor valve 115. An example of such a heated vapor valve is valve P/N SS-8BK-VV-1C by Swagelok of Sunnyvale, Calif., with heater P/N 030630-41 by Nor-Cal Products of Yreka, Calif. The vapor chamber manometer 112 monitors the pressure inside vapor chamber 110. The process oven 104 may contain one or more trays 105.

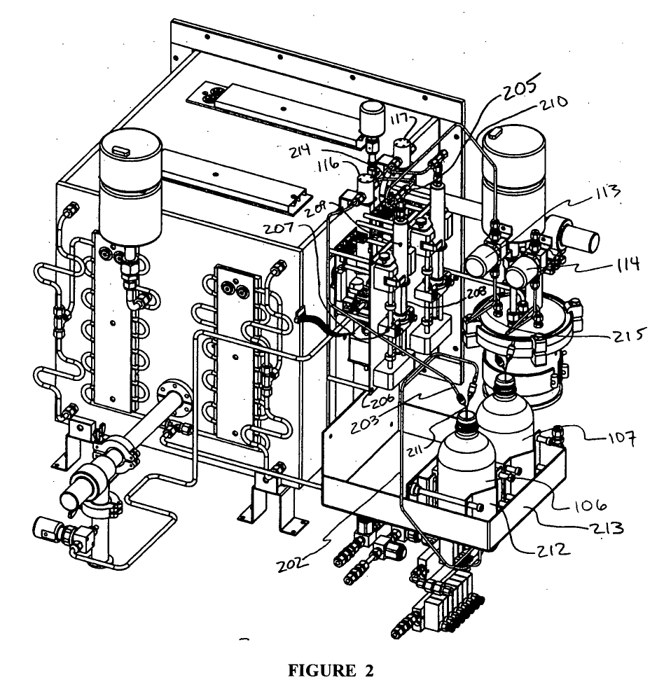

In one embodiment of the present invention, as seen in FIG. 2, fluid input portion 102 routes chemicals from the fluid reservoir 106 through a delivery pipe 203 to the chemical withdraw valve 116. An example of such a chemical withdraw valve 116 is P/N 6LVV-DP11811-C manufactured by Swagelok of Sunnyvale, Calif. A fluidic coupler 211 is inserted into fluid reservoir 106 to allow fluid withdrawal from the fluid reservoir 106. In this embodiment, the fluid reservoirs 106, 107, are chemical source bottles. The fluidic coupler 211 also allows fluid such as dry nitrogen gas from pipe 202 to be inserted into the chemical reservoir 106 to fill the volume voided by the removal of chemical from the chemical reservoir 106. Exposure of the chemical to air and/or moisture is thus minimized. The syringe pump 206 may withdraw chemicals from fluid reservoir 106 when the chemical withdraw valve 116 is opened. An example of the syringe pump 206 is P/N 981948 manufactured by Harvard Apparatus, of Holliston, MASS. Actuation of the syringe pump mechanism 207 withdraws chemicals from the fluid reservoir 106 by partially or fully withdrawing the syringe plunger 208 from the syringe body 209. The amount of chemical withdrawn may be pre-determined, and also may be pre-determined with accuracy. The chemical is routed from the fluid reservoir 106, through the fluidic coupler 211 and the delivery pipe 203 to the chemical withdraw valve 116, through a pipe 214 and a T-coupler 205 to the syringe body 209 in this embodiment. In general, fluidic coupling can be referring to liquid or gas coupling in this embodiment.

After withdrawal of chemicals into the syringe body 209, the chemical withdraw valve 116 may be closed to isolate the delivery pipe 203. The chemical infusion valve 113 may then be opened to link the syringe body 209 to the vapor chamber 110. An example of such a chemical infusion valve 113 is P/N 6LVV-DP11811-C manufactured by Swagelok of Sunnyvale, Calif. The syringe pump mechanism 207 may then re-insert the syringe plunger 208 partially or fully into the syringe body 209, forcing the chemical within the syringe body 209 through the T-coupler 205 and then through pipe 210. With the chemical infusion valve 113 open, the chemical then may enter the vapor chamber 110 via pipe 215. Pressure within the vapor chamber 110 is monitored with the vapor chamber manometer 112. An example of such a manometer is a 0-100 Torr heated capacitance manometer P/N 631A12TBFP manufactured by MKS of Andover, Md.

The fluid reservoir 106 is secured with a spring clamp 212 within a source bottle tray 213. The source bottle tray 213 may also act as a spill containment vessel.

In some embodiments of the present invention, the fluid input portion 102 delivers the desired amount of chemical in another way. The chemicals in the fluid reservoirs are withdrawn in a pre-determined amount using a metering pump. For example, the metering pump may withdraw and deliver 2 milliliters per stroke. To deliver a specific quantity of a chemical, the metering pump would be pumped repeatedly until the desired quantity had been delivered.

One of skill in the art will understand that the fluid input portion may have other embodiments that may use the above described elements in different types of combinations, or may use different typed of elements.

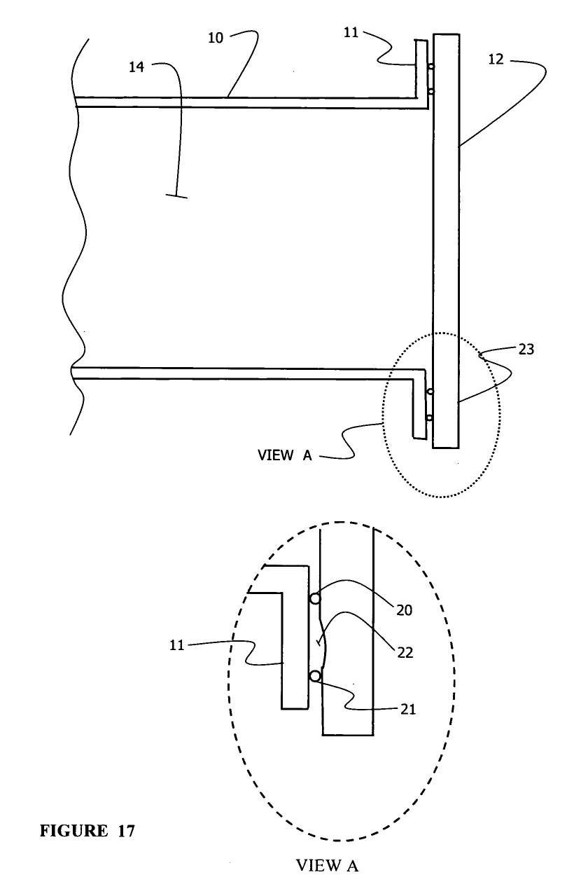

Many processes are sensitive to oxygen and require extremely low oxygen levels. In fact, many purge gas suppliers take great pride in the extremely low oxygen content of their gasses. Other sources of oxygen contamination exist. Any leak in a vacuum apparatus may allow oxygen from the manufacturing lab to enter the vacuum chamber. In some embodiments of the present invention, as seen in FIG. 17, a system is utilized to reduce or eliminate the entrance of oxygen into the vacuum chamber via the process apparatus door. The vacuum (or process) chamber door 12 seals one end of the vacuum chamber 10. The vacuum chamber door 12 opens and closes so as to provide access to the inside of the vacuum chamber 10 to allow items to be inserted or removed from the vacuum chamber 10. In some embodiments, the vacuum chamber 10 has a main chamber 14 adapted to receive substrates to be coated and their associated handling fixtures. The vacuum chamber door 12 has an overlap portion 23 which overlays onto the chamber flange 11 in some embodiments. A first seal 20 around the periphery of the chamber flange provides a circumferential vacuum seal between the door 12 and the vacuum chamber 10. A second seal 21 provides a second circumferential seal around the periphery of the chamber flange further out radially than the first seal 20. In some embodiments, the first seal 20 and the second seal 21 are O-rings. A door seal cavity 22 is located between the first seal 20 and the second seal 21. A door seal cavity gas conduit provides gas into the door seal cavity 22. In some embodiments, the door seal cavity gas conduit provides an inert gas into the door gas cavity 22. In some embodiments, the door gas is nitrogen. In some embodiments, the door gas is provided at 1.1 atm of pressure. By providing inert gas at greater than atmospheric pressure, any vacuum leak in the first seal 20 will result in the induction of the inert door gas and not in the induction of the atmosphere outside in the manufacturing lab. This will preserve the extremely low oxygen environment in the process chamber. A door seal cavity vacuum conduit may also be present in some embodiments. The door seal cavity vacuum conduit allows for the evacuation of the door seal cavity. In some process uses, the door seal gas cavity will first be evacuated, and then filled with inert gas at a pressure slightly greater than atmospheric pressure.

Although the double door seal described above is illustrated with the embodiment of a deposition system disclosed herein, the double door seal may be used with a variety of systems. For example, other silane deposition systems which utilize bulk heating of the silane compound also face contamination concerns. Thus, any process chamber utilized in silane compound processing may utilize the door seal according to some embodiments of the present invention.

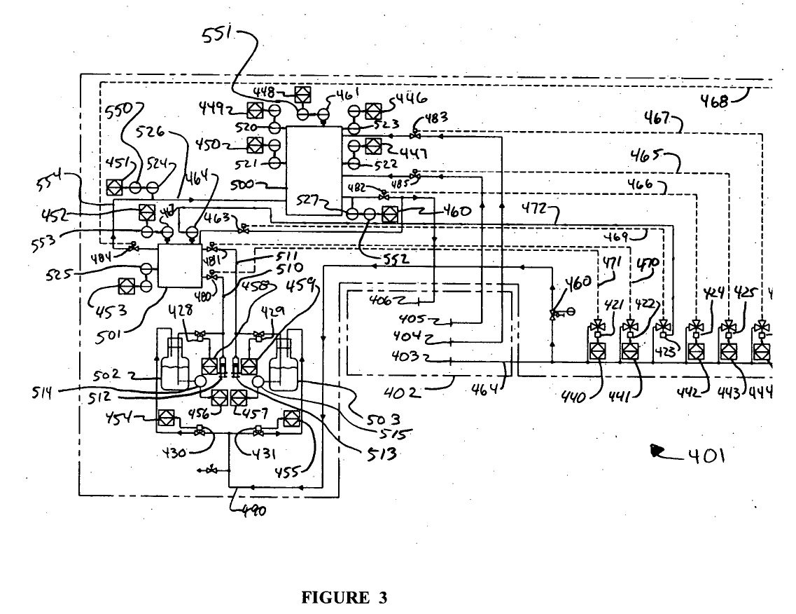

In one embodiment of the present invention, as seen in FIG. 3, piping and other hardware is arranged as illustrated in the piping schematic 401. Vacuum and gas portion 402 illustrates the portion of the apparatus with inputs for gas and the provision of vacuum. In one embodiment of the present invention, a high pressure gas inlet 403 connects to 80-100 psig nitrogen, an inlet 404 connects to 5-15 psig of a process gas, and an inlet 405 connects to 15-40 psig nitrogen. A vacuum inlet 406 provides vacuum to the system.

The high pressure gas inlet 403 provides gas via a line 464 to the chemical reservoirs 502, 503, and also provides the pressure to actuate valves 463 and valves 480-484. Solenoids 421-427 are directed by a logic controller at I/O locations 440-445 to actuate valves 480-485 using solenoids 421-427. The gas from the high pressure gas inlet 403 is reduced in pressure to 4 psig by a pressure reducer 460 to be fed to the chemical reservoirs.

The solenoid acutated valves 430, 431 are triggered by directions from a logic controller at I/O interfaces 454, 455 to allow for purging of the chemical source bottle feed line 490.

When the solenoid 421 is directed by the logic controller via the I/O interface 440, high pressure gas is directed through a line 471 to actuate the chemical infusion valve 480, which connects the fluid line 510 from the syringe pump 512 to the vaporization chamber 501. When the solenoid 422 is directed by the logic controller via the I/O interface 441, high pressure gas is directed through the line 470 to actuate the chemical infusion valve 481, which connects the fluid line 511 from the syringe pump 513 to the vapor chamber 501.

When the solenoid 426 is directed by the logic controller via the I/O interface 444, high pressure gas is directed through the line 467 to actuate valve 483 which allows for the introduction into the process chamber 500 of gas from the inlet 404. When the solenoid 425 is directed by the logic controller via the I/O interface 443, high pressure gas is directed through the line 465 to actuate the valve 485, which allows for the introduction into the process chamber 500 of gas from the inlet 405.

When the solenoid 427 is directed by the logic controller via the I/O interface 445, high pressure gas is directed through a line 468 to actuate the heated vapor valve 484, which allows for the introduction into the process chamber 500 of vaporized chemical from the vapor chamber 501 via line 554. Temperature indicating controller 524 and temperature alarm high switch are coupled to I/O interface 451.

Solenoid operated valves 428, 429 allow the opening and closing of lines between the chemical reservoirs 502, 503 and the syringe pumps 512, 513. I/O interfaces 458, 459 control the operation of the solenoid operated valves 428, 429.

The level of chemical left in the chemical reservoirs 502, 503 is monitored with level sensors 514, 515 and routed to the logic controller via the I/O interfaces 456, 457. Level sensors 514, 515 are capacitance level switches P/N KN5105 by IFM Effector of Exton, Pa., in this embodiment.

The vapor chamber pressure switch 464 is linked directly by a line 472 to a solenoid actuated valve 423, which, when triggered, in turn triggers the gas actuated overpressurization limit relief valve 463. The overpressurization limit relief valve 463 connects the vapor chamber 501 to the vacuum line inlet 406. The vapor chamber pressure switch 464 triggers when the pressure in the vapor chamber 501 exceeds a preset pressure, which is 650 Torr in this embodiment.

The process oven manometer 461 feeds its signal to the logic controller via an analog interface (not shown). Overtemperature alarm 551 feeds its signal to the logic controller via I/O interface 448. An I/O interface 442 controls the solenoid actuated valve 424, which in turn can trigger the gas actuated heated vacuum valve 482 via a line 466, which links the process oven 500 to the vacuum inlet 406. A temperature monitor 527 monitors the vacuum line temperature and is linked to the logic controller via an I/O interface 460. Temperature alarm high switch 552 is linked to the logic controller via an I/O interface 460.

Temperature monitors 520, 521, 522, 523 monitor the temperature in the process oven 500. Temperature monitors 520, 521, 522, 523 are linked to the logic controller by an RS-485 interface (not shown). Alarms are present in the temperature monitoring system and are linked to the logic controller by I/O interfaces 446, 447, 449, 450.

Temperature monitors 524, 525 connected to I/O interfaces 451, 453 are also used to monitor the temperature of the heated vapor line 526 and the vapor chamber 501. A pressure monitor 462 is linked to the logic controller by an analog interface and overtemperature alarm 553 is linked to the logic controller by an I/O interface 452.

A logic controller may be used to control this apparatus in some embodiments. An example of such a controller is Control Technology Corporation Model 2700 of Hopinkton, Mass. One of skill in the art will understand that the apparatus may be controlled using a variety of suitable methods.

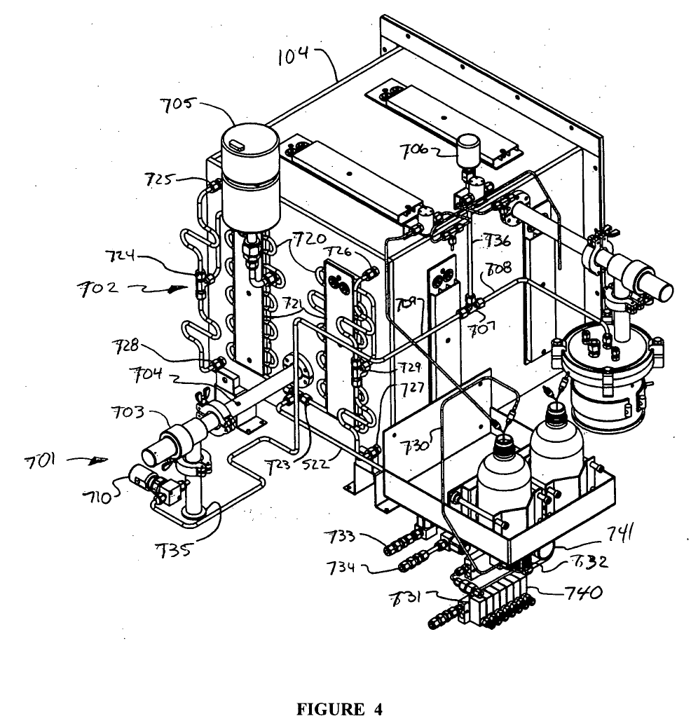

In one embodiment of the present invention, as seen in FIG. 4, a chemical vapor deposition apparatus 101 has a vacuum subsystem 701. Vacuum is applied to the vacuum subsystem 701 vacuum input supply line 735. A heated vacuum valve 703 may be actuated to isolate the heated vacuum line 704 from the vacuum input supply line 735. An example of the heated vacuum valve is P/N SS-8BK-VV-1C manufactured by Swagelok of Sunnyvale, Calif. The vacuum in the process chamber is measured using the chamber manometer 705. An example of such a manometer is P/N 631A13TBFP manufacture by MKS of Andover, Md. Vacuum input supply line is fluidically coupled to the overpressurization limit relief valve 710. An example of such a overpressurization limit relief valve is P/N SS-BNVS4-C manufactured by Swagelok of Sunnyvale, Calif. Overpressurization limit relief valve 710 couples vacuum input supply line 735 to line 709. T-coupler 707 links line 708, line 709, and line 736. Line 736 is fluidically coupled to vapor flask overpressurization limit switch 706. The overpressurization limit switch 706 is electrically connected to a solenoid actuated valve which supplies high pressure gas that actuates the overpressurization limit relief valve 710. An example of the vapor flask overpressurization limit switch is P/N 51A13TCA2AF650 by MKS of Andover, Md. Line 708 is fluidically coupled to vapor chamber 110.

A low pressure gas distribution manifold 733 distributes gas such as dry nitrogen for use in dehydration cycles. Inert gas such as dry nitrogen may be used in these lines. A purge manifold 732 allows for the purging of the fluid reservoirs and lines. The low pressure gas input line 522 is split at a T-coupler 723 into two serpentine lines 720. Gas line heaters 721 allow for the pre-heating of the gas prior to delivery of the process chamber. T-couplers 724, 729 further divide the delivery lines prior to input to the chamber at the gas inlets 725, 726, 727, 728.

A high pressure gas distribution manifold 731 provides gas for purge manifold 732 which inserts low pressure nitrogen into the fluid reservoirs 106, 107. A line 730 routes gas to a fluidic coupler 211 in order to replace the volume voided by chemical withdrawal. Inert gas such as dry nitrogen may be used in these lines. The regulator 741 reduces the pressure from manifold 731 upstream from purge manifold 732.

High pressure gas distribution manifold 731 provides high pressure gas that is routed to the gas actuated valves by the triggering of solenoid actuated valves in valve bank 740.

An alternative process gas distribution inlet 734 provides another inlet for process gas that may be used in some processes using this embodiment of the present invention. In this embodiment, the process gas lines are fluidically coupled to the low pressure gas lines upstream of the serpentine lines 720.

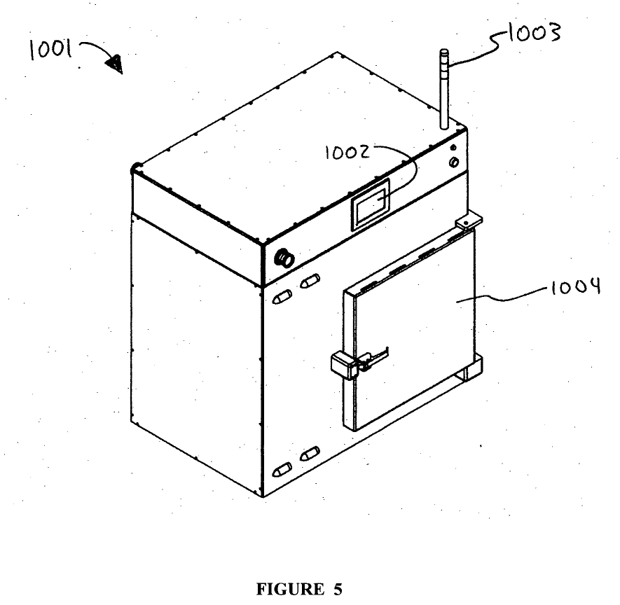

As seen in FIG. 5, chemical vapor reaction apparatus 1001 has a touchpanel interface 1002. The light tower 1003 signals status of the apparatus to persons in the vicinity. Door 1004 provides access to the process chamber.

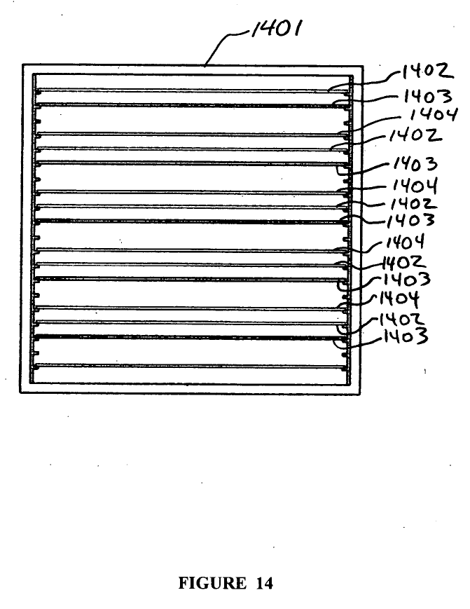

In some embodiments of the present invention, as seen in FIG. 14, the process oven 104 houses a plasma gas generation system. The plasma gas generation system resides predominantly within the process oven chamber walls 1401. The gas plasma generation system is adapted to generate gas plasma within the process oven 104. In some embodiments, the product trays 1404 span the process oven 104. Active electrodes 1402 and ground electrodes 1403 span the process oven 104 horizontally. The RF power supply, cabling, and feed throughs are known in the art.

In some embodiments, the plasma cleaning cycle may occur before the dehydration process. In an exemplary process, the chamber is evacuated. A gas is then introduced into the chamber and the pressure is stabilized at a low pressure, such as 2 milliTorr. In some embodiments, the introduced gas in oxygen. In some embodiments, the introduced gas is a combination of oxygen and argon. In some embodiments, other gasses are used.

The plasma gas generation system allows for plasma gas cleaning of a work piece, such as a slide or substrate, in the same chamber as that in which subsequent process steps will take place. This gives many advantages, including reducing possible contamination that may occur if the work piece is exposed to the environment after plasma cleaning. Also, the plasma gas generation system can be used to clean the oven after the work pieces have been processed and removed. Many of the chemicals that may be used in processes that this chamber supports may leave residues that can interfere with subsequent runs. The plasma gas generation system may be utilized to clean the chamber after a process run and prior to loading the chamber with the work pieces for the next run.

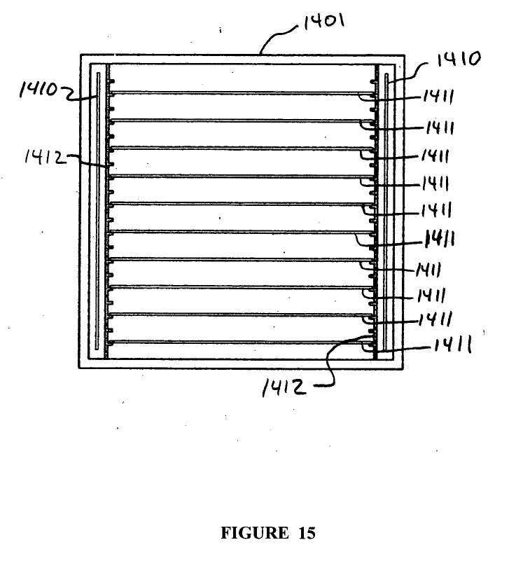

In some embodiments, as seen in FIG. 15, the active electrodes 1410 and the ground electrodes 1412 may span the interior of the process oven 104 vertically. The product trays 1411 may span the process oven 104 horizontally between the ground electrodes 1412.

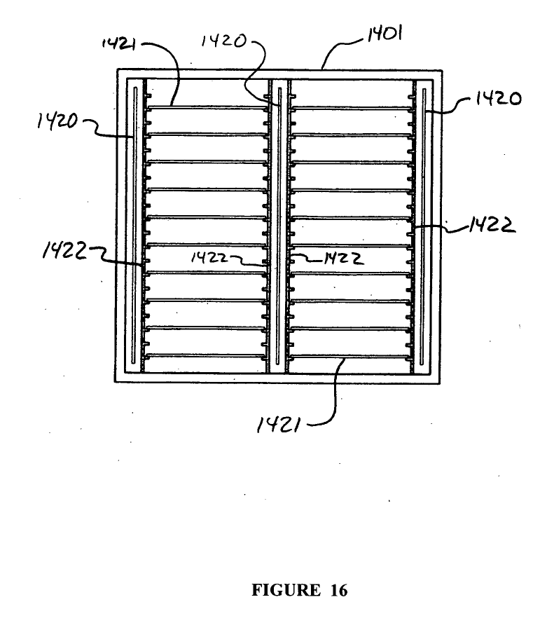

In some embodiments, as seen in FIG. 16, there may be a plurality of vertical segments within the process oven 104. The ground electrodes 1422 and the active electrodes 1420 reside vertically within the process oven 104. The product trays 142 reside horizontally between ground electrodes 1422.

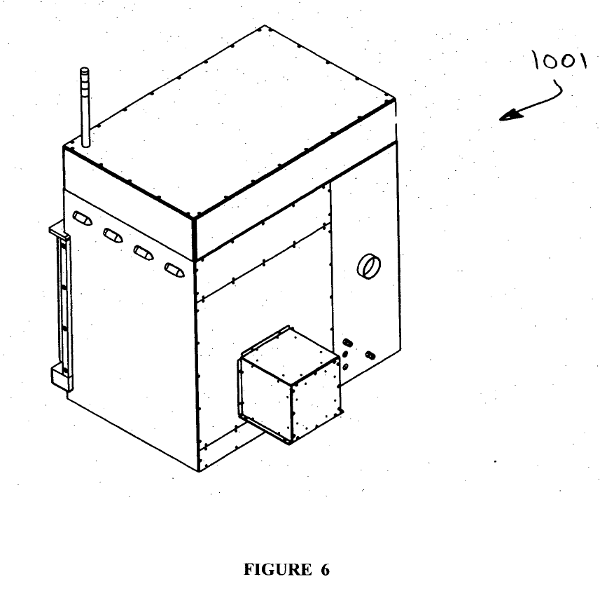

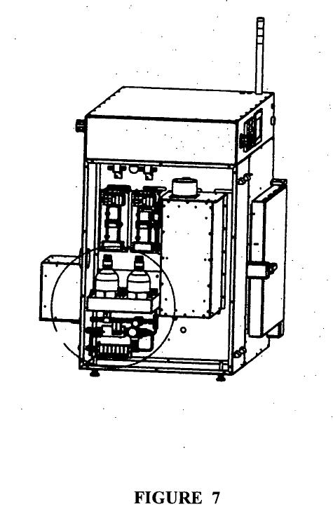

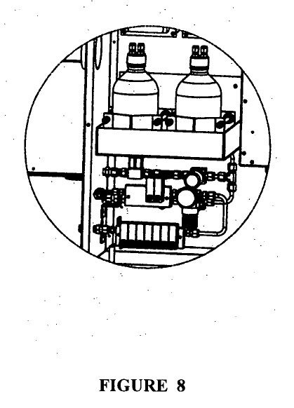

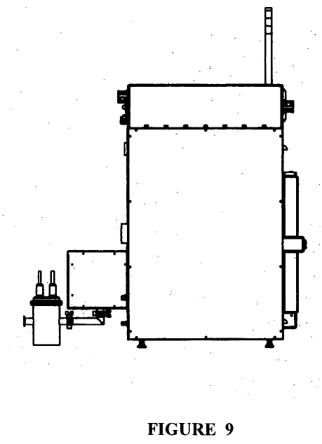

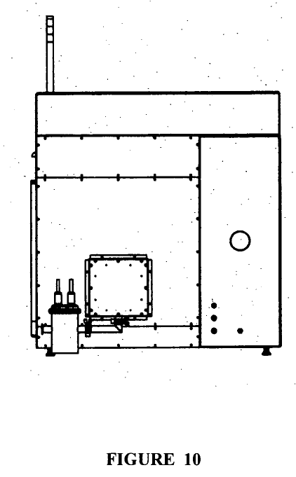

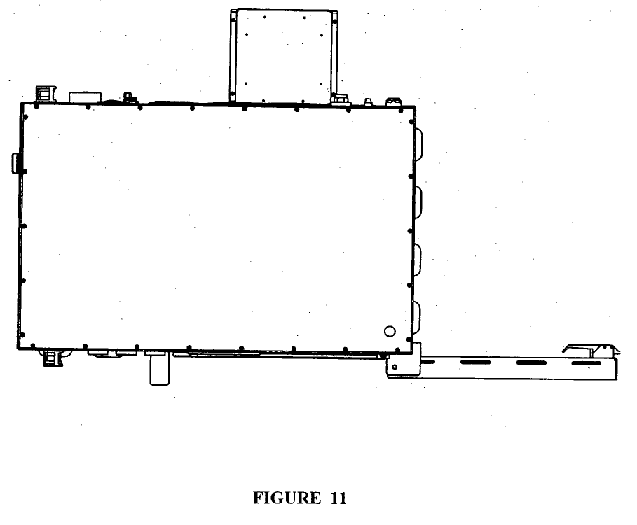

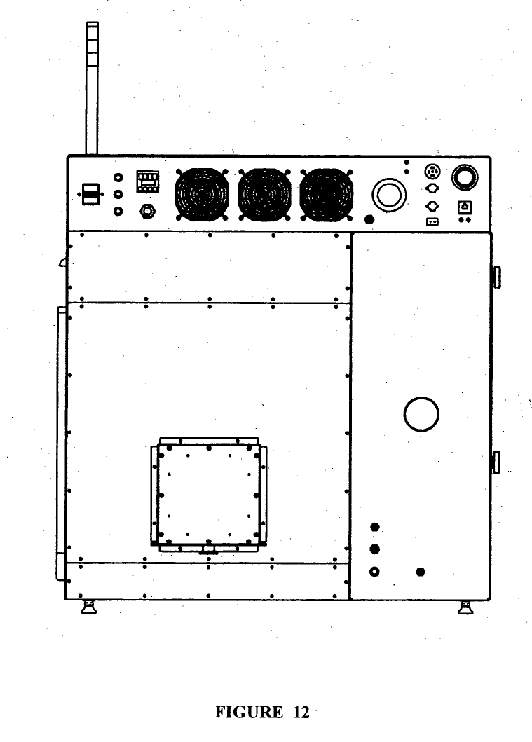

FIG. 6 shows a rear isometric view of apparatus 1001. FIG. 7 is a partial cutaway side view of one embodiment of the present invention. FIG. 8 is a blown up section of the partial side view of FIG. 7. FIG. 9 is a side view of one embodiment of the present invention. FIG. 10 is a rear view of one embodiment of the present invention. FIG. 11 is a top view of one embodiment of the present invention with the process door open. FIG. 12 is a rear view of one embodiment of the present invention.

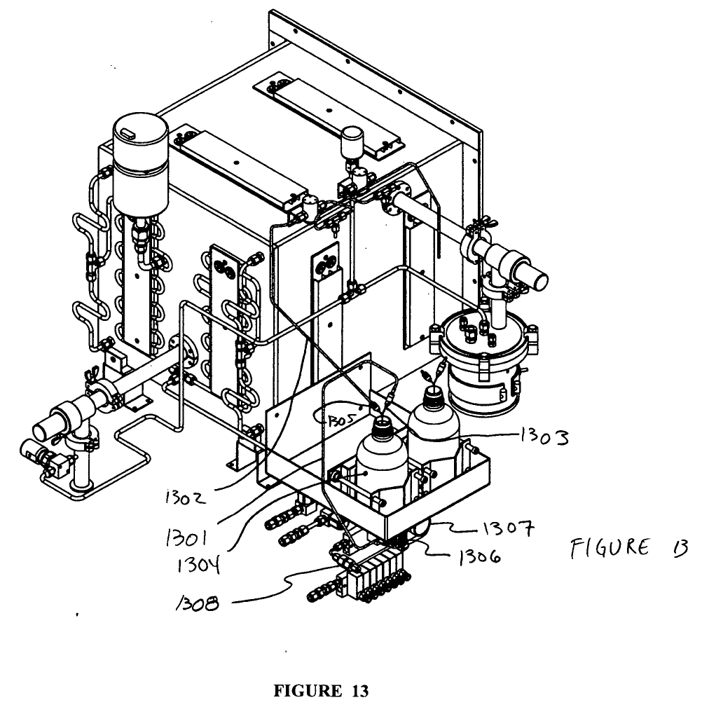

FIG. 13 is a cutaway view of the vacuum subsystem and the chemical reservoir purge subsystem. A manufacturer's chemical source bottle 1304 is the chemical reservoir in this embodiment. The purge regulator 1307 feeds the purge manifold 1306 with a gas such as nitrogen. A 5 psi relief valve 1308 is located downstream from the purge manifold in this embodiment. Gas is routed to the bottle 1304 via a line 1301. Line 1301 connects to a fitting 1303 which routes the gas from line 1301 into the head portion of the source bottle 1304. The withdrawal line 1302 couple to the fitting 1305 for withdrawal of the chemical from the source bottle 1304. The tube supplying chemical to the withdrawal line 1302 terminates near the bottom of the inside of source bottle 1304. Line 1301 is delivered gas from the purge manifold 1306.

A process for the coating of substrates in a process chamber, which may include dehydrating the substrate, gas plasma cleaning of the substrate, and vaporizing the chemical to be reacted prior to its entry into the process chamber. Subsequent to the processing of the substrate, the chamber may be cleaned using gas plasma.

A substrate for the chemical deposition of different chemicals may be of any of a variety of materials. For biotech applications, a glass substrate, or slide, is often used. Glass substrates may be borosilicate glass, sodalime glass, pure silica, or other types. Substrate dehydration may be performed as part of some processes. The glass slide is inserted into the process chamber. The slide is then dehydrated. Residual moisture interferes with the adhesion of chemicals during the deposition process. Alternatively, dehydration of the slide allows for later rehydration in a controlled fashion. The dehydration process alternates exposing the glass slide to vacuum and then to heated nitrogen, either once or multiple times. For example, the glass slide would be exposed to a vacuum of 10 Torr for 2 minutes. At this pressure water boils at about 11 C. The vacuum chamber would then be flooded with preheated nitrogen at 150 C. This part of the process would heat the surface of the glass slide so that the high temperature of the slide would assist in the dehydration process as vacuum was once again applied. After 3 complete cycles, a vacuum of 1 Torr would be applied to complete the dehydration process.

A gas plasma cleaning cycle may also be used in preparation of the substrate for coating. In a typical process, the substrate is cleaned using gas plasma after the dehydration process. In some embodiments, the plasma cleaning cycle may occur before the dehydration process. In an exemplary process, the chamber is evacuated. A gas is then introduced into the chamber and the pressure is stabilized at a low pressure, such as 2 milliTorr. In some embodiments, the introduced gas in oxygen. In some embodiments, the introduced gas is a combination of oxygen and argon. In some embodiments, other gasses are used. After the stabilization of the pressure in the process chamber, the electrodes are powered to generate the plasma. In an exemplary process, the electrodes are powered to 450 Volts cycled at 40 kiloHertz. The power cycle may last for 2 minutes in some embodiments.

After the completion of the dehydration and plasma cleaning cycles, the slide or substrate is ready for chemical reaction. Chemical reservoirs, such as manufacturer's source bottles, provide the chemical for the deposition process. For many processes, silanes are used. Among the silanes used are amino silanes, epoxy silanes, and mercapto silanes. Chemical may be withdrawn directly from the reservoir. A metered amount of chemical is withdrawn from the chemical reservoir. This may be done by opening a valve between the chemical reservoir and a withdrawal mechanism. The withdrawal mechanism may be a syringe pump. Chemical is withdrawn from the reservoir, enters the syringe pump, and then the valve between the chemical reservoir and the syringe pump is closed. The chemical reservoirs may be purged with an inert gas such as nitrogen. This purging allows for the filling of the volume of fluid removed with an inert gas, minimizing contact between the chemical in the reservoir and any air or moisture.

Next, a valve between the syringe pump and a vaporization chamber is opened. The vapor chamber may be pre-heated. The vapor chamber may be a reduced pressure. The syringe pump then pumps the previously withdrawn chemical from the syringe pump to the vaporization chamber. The vapor chamber may be at the same vacuum level as the process oven. In parallel to this delivery of chemical to the vaporization chamber, a second chemical may be undergoing the same delivery process. The two chemicals may vaporize at substantially the same time. Additionally, more chemicals may also be delivered to the vaporization chamber, or to another vaporization chamber.

In some embodiments, the chemical or chemicals to be vaporized may be withdrawn from the reservoir or reservoirs in a specific metered amount. This specific amount of withdrawal and delivery to the vapor chamber may be repeated until the desired amount of chemical or chemicals has been delivered into the vapor chamber. For example, a metering pump may be used. The metering pump may deliver a pre-determined amount of chemical per stroke of the metering pump. The number of pump strokes may be selected, thus delivering a specified amount of chemical.

The reduced pressure in the vapor chamber, and/or the elevated temperature in the vapor chamber may allow for the vaporization of chemicals at pre-determined pressure levels and temperatures.

The vaporized chemical, or chemicals, are then delivered to the process chamber. This may be done by opening a valve between the vaporization chamber and the process oven after the chemical has vaporized in the vaporization chamber. Alternatively, the valve between the vaporization chamber and the process oven may already be open when the chemical, or chemicals, are delivered to the vaporization chamber. The chemical then proceeds into the process chamber and reacts with the substrate.

In some embodiments, the chemical may be added into the vapor chamber with the valve between the vapor chamber and the process chamber open. The chemical may be continued to be added into the vapor chamber until the vapor pressure in the process chamber reaches a desired level. At that time, the valve between the vapor chamber and the process chamber may be closed. The chemical may then remain in the process chamber for the desired amount of time for reaction.

In some embodiments, the chamber may be cleaned using gas plasma subsequent to the processing steps. The chamber may be emptied of all workpieces and then cleaned. The gas plasma cleaning step subsequent to the processing steps helps prepare the process chamber for subsequent processing.

As evident from the above description, a wide variety of embodiments may be configured from the description given herein and additional advantages and modifications will readily occur to those skilled in the art. The invention in its broader aspects is, therefore, not limited to the specific details, representative apparatus and illustrative examples shown and described. Accordingly, departures from such details may be made without departing from the spirit or scope of the applicant's general invention.

We claim:

1. A chemical vapor reaction apparatus comprising:
a silane input portion; said silane input portion is adapted to deliver silane to a process chamber;
a process chamber, said process chamber including a first opening;
a door, said door adapted to cover said first opening,
a first seal, said first seal adapted to seal between said door and said process chamber around said first opening; and
a second seal, said second seal adapted to seal around said first seal.

2. The chemical vapor reaction apparatus of claim 1 further comprising a door seal cavity, said door seal cavity formed between said first seal and said second seal when said door is closed onto said process chamber.

3. The chemical vapor reaction apparatus of claim 2 further comprising a door seal cavity gas conduit, said door seal cavity gas conduit adapted to provide gas to said door seal cavity.

4. The chemical vapor reaction apparatus of claim 2 further comprising a door seal cavity vacuum conduit, said door seal cavity vacuum conduit adapted to provide vacuum to said door seal cavity.

5. A chemical vapor reaction apparatus comprising:
a vacuum chamber, said vacuum chamber including a first opening;
a door, said door adapted to cover said first opening;
a first seal, said first seal adapted to seal between said door and said vacuum chamber around said first opening;
a second seal, said second seal adapted to seal around said first seal;
a vapor chamber, said vapor chamber fluidically coupled to said vacuum chamber, said vapor chamber fluidically isolatable from said vacuum chamber; and
a chemical delivery system, said chemical delivery system fluidically coupled to said vapor chamber, said chemical delivery system fluidically isolatable from said vapor chamber.

6. The chemical vapor reaction apparatus of claim 5 further comprising a door seal cavity, said door seal cavity formed between said first seal and said second seal when said door is closed onto said process chamber.

7. The chemical vapor reaction apparatus of claim 6 further comprising a door seal cavity gas conduit, said door seal cavity gas conduit adapted to provide gas to said door seal cavity.

8. The chemical vapor reaction apparatus of claim 6 further comprising a door seal cavity vacuum conduit, said door seal cavity vacuum conduit adapted to provide vacuum to said door seal cavity.

9. A chemical vapor reaction apparatus comprising:
a vacuum chamber, said vacuum chamber including a first opening;
a door, said door adapted to cover said first opening;
a first seal, said first seal adapted to seal between said door and said vacuum chamber around said first opening;
a second seal, said second seal adapted to seal around said first seal;
a vapor chamber, said vapor chamber fluidically coupled to said vacuum chamber, said vapor chamber fluidically isolatable from said vacuum chamber;
a gas plasma portion, said gas plasma portion adapted to generate gas plasma within said process chamber; and
a chemical delivery system, said chemical delivery system fluidically coupled to said vapor chamber, said chemical delivery system fluidically isolatable from said vapor chamber.

10. The chemical vapor reaction apparatus of claim 9 wherein said plasma portion comprises:
a ground electrode; and
an active electrode.

11. The chemical vapor reaction apparatus of claim 10 wherein said plasma portion further comprises an RF power supply, said RF power supply electrically connected to said ground electrode and said active electrode.

12. The chemical vapor reaction apparatus of claim 11 further comprising a door seal cavity, said door seal cavity formed between said first seal and said second seal when said door is closed onto said process chamber.

13. The chemical vapor reaction apparatus of claim 12 further comprising a door seal cavity gas conduit, said door seal cavity gas conduit adapted to provide gas to said door seal cavity.

14. The chemical vapor reaction apparatus of claim 12 further comprising a door seal cavity vacuum conduit, said door seal cavity vacuum conduit adapted to provide vacuum to said door seal cavity.

15. A process for coating of substrates comprising:
inserting a substrate into a process chamber;
supplying a first silane to a heated vaporization chamber, said heated vaporization chamber fluidically coupled to and fluidically isolatable from said process chamber;
vaporizing said first silane; and
supplying the vapor of said first silane to said process chamber, thereby coating said substrate with said first silane.

16. The process of claim 15 further comprising sealing the door of said process chamber with a first seal and a second seal, said second seal adapted to seal around said first seal.

17. The process of claim 16 further comprising reducing the pressure in the cavity between said first seal and said second seal.

18. The process of claim 16 further comprising supplying gas to the cavity between said first seal and said second seal.

19. The process of claim 18 further comprising plasma cleaning said substrate in the process chamber
